(19) United States
(12) Patent Application Publication
(10) Pub. No.: US 2025/0248065 A1
(43) Pub. Date: Jul. 31, 2025

(54) SEMICONDUCTOR DEVICE AND METHOD FOR MANUFACTURING THE SAME

(71) Applicant: DENSO CORPORATION, Kariya-city (JP)

(72) Inventors: Yasuhiro HIRABAYASHI, Kariya-city (JP); Yuichi TAKEUCHI, Kariya-city (JP)

(21) Appl. No.: 19/182,420

(22) Filed: Apr. 17, 2025

Related U.S. Application Data
(63) Continuation of application No. PCT/JP2023/028484, filed on Aug. 3, 2023.

(30) Foreign Application Priority Data
Oct. 19, 2022 (JP) 2022-167823

(51) Int. Cl. H10D 30/66; H01L 21/265; H10D 62/10; H10D 84/83

(52) U.S. Cl. CPC H10D 30/665; H10D 62/107; H10D 84/839; H01L 21/265

(57) ABSTRACT

A semiconductor device includes a semiconductor substrate having an element region and an outer peripheral region around the element region, and an upper electrode in contact with an upper surface the semiconductor substrate in the element region. The element region includes a p-type main region in contact with the upper electrode, and an n-type element drift region below the main region. The outer peripheral region includes a plurality of p-type guard rings disposed in multiple ring shapes surrounding the element region, a plurality of n-type spacing regions disposed between the guard rings, and an n-type outer drift region continuous with the element drift region and located below the guard rings and the spacing regions. At least one of the spacing regions is a high concentration spacing region having an n-type impurity concentration higher than that of the element drift region.

### CROSS REFERENCE TO RELATED APPLICATIONS

The present application is a continuation application of International Patent Application No. PCT/JP2023/028484 filed on Aug. 3, 2023, which designated the U.S. and claims the benefit of priority from Japanese Patent Application No. 2022-167823 filed on Oct. 19, 2022. The entire disclosures of all of the above applications are incorporated herein by reference.

### TECHNICAL FIELD

The present disclosure relates to a semiconductor device and a method for manufacturing the semiconductor device.

### BACKGROUND

For example, it has been known a semiconductor device having a semiconductor substrate provided with an element region and an outer peripheral region. The element region is, for example, formed with a metal oxide semiconductor field effect transistor (MOSFET). The outer peripheral region is disposed on a periphery of the element region. The outer peripheral region is provided with a plurality of p-type guard rings each having a ring shape and disposed in multiple surrounding the element region. When such a semiconductor device is turned off, a depletion layer spreads from the element region to the outer peripheral region. At this time, the depletion layer spreads to the outer peripheral region through the guard rings. Since the depletion layer spreads in the outer peripheral region in this manner, the voltage can be maintained in the outer peripheral region.

### SUMMARY

The present disclosure describes a semiconductor device. According to an aspect, a semiconductor device includes: a semiconductor substrate having an element region and an outer peripheral region on an outer periphery of the element region; and an upper electrode in contact with an upper surface the semiconductor substrate in the element region. The element region includes a p-type main region in contact with the upper electrode, and an n-type element drift region below the main region. The outer peripheral region includes a plurality of p-type guard rings disposed in multiple ring shapes surrounding the element region, a plurality of n-type spacing regions disposed between the plurality of guard rings, and an n-type outer drift region continuous with the element drift region and located below the plurality of guard rings and the plurality of spacing regions. At least one of the plurality of spacing regions is a high concentration spacing region having an n-type impurity concentration higher than that of the element drift region.

### BRIEF DESCRIPTION OF DRAWINGS

Features and advantages of the present disclosure will become more apparent from the following detailed description made with reference to the accompanying drawings, in which:

FIG. 1 is a cross-sectional view of a semiconductor device, which is taken along a line I-I in FIG. 2, according to an embodiment of the present disclosure;

FIG. 2 is a plan view of the semiconductor device according to the embodiment of the present disclosure;

FIG. 3 is a diagram illustrating an electric field distribution in an outer peripheral region;

FIG. 4 is a graph illustrating the electric field distribution at a line IV-IV in FIG. 3;

FIG. 5 is a diagram illustrating a non-depletion region in a case where the width of a guard ring is large;

FIG. 6 is a diagram illustrating a non-depletion region in a case where the width of the guard ring is small;

FIG. 7 is a diagram explaining a manufacturing method of the semiconductor device according to the embodiment;

FIG. 8 is a diagram explaining the manufacturing method of the semiconductor device according to the embodiment;

FIG. 9 is a diagram explaining the manufacturing method of the semiconductor device according to the embodiment;

FIG. 10 is a cross-sectional view of a semiconductor device according to a first modification;

FIG. 11 is a cross-sectional view of a semiconductor device according to a second modification;

FIG. 12 is a cross-sectional view of a semiconductor device according to a third modification;

FIG. 13 is a cross-sectional view of a semiconductor device according to a fourth modification;

FIG. 14 is a cross-sectional view of a semiconductor device according to a fifth modification;

FIG. 15 is a cross-sectional view of a semiconductor device according to a sixth modification;

FIG. 16 is a cross-sectional view of a semiconductor device according to a seventh modification;

FIG. 17 is a cross-sectional view of a semiconductor device according to an eighth modification;

FIG. 18 is a cross-sectional view of a semiconductor device according to a ninth modification; and

FIG. 19 is a cross-sectional view of a semiconductor device according to a tenth modification.

### DETAILED DESCRIPTION

In a semiconductor device having a semiconductor substrate formed with an element region and an outer peripheral region on an outer periphery of the element region, if the outer peripheral region is wide, the area ratio occupied by the element region in the entire semiconductor substrate is small. Thus, it is difficult to allow current to flow through the semiconductor substrate at high density.

The present disclosure provides a semiconductor device which is capable of achieving a high breakdown voltage by means of a narrow outer peripheral region, and a method for manufacturing the semiconductor device.

In an embodiment of the present disclosure, a semiconductor device includes a semiconductor substrate and an upper electrode. The semiconductor substrate has an element region and an outer peripheral region on a periphery of the element region. The upper electrode is disposed in contact with an upper surface of the semiconductor substrate in the element region. The element region has a p-type main region in contact with the upper electrode and an n-type element drift region located below the main region. The outer peripheral region has a plurality of guard rings, a plurality of n-type spacing regions, and an n-type outer drift region. Each of the plurality of guard rings has a ring shape and the guard rings are disposed in multiple ring shapes surrounding the element region when the semiconductor substrate is viewed in a thickness direction. The spacing regions are disposed between the guard rings. The outer drift region is continuous with the element drift region and is disposed below the guard rings and the spacing regions. At least one of the spacing regions is a high concentration spacing region having an n-type impurity concentration higher than that of the element drift region.

When the semiconductor device is turned off, a depletion layer spreads from the element region to the outer peripheral region. At this time, the depletion layer spreads to the outer peripheral region (i.e., to the respective spacing regions and the outer drift region) through the respective guard rings. At least one of the plurality of spacing regions is the high concentration spacing region having the n-type impurity concentration higher than that of the element drift region. Since fixed charges (i.e., donors) are present in the high concentration spacing region at a high concentration, when the high concentration spacing region is depleted, a high electric field is generated in the high concentration spacing region. Thus, a high voltage can be maintained between a pair of guard rings disposed at opposite sides of the high concentration spacing region. Accordingly, the semiconductor device can achieve a high breakdown voltage by the outer peripheral region even with a small width.

In an embodiment of the semiconductor device disclosed herein, the semiconductor substrate may be formed with a plurality of gate trenches in the upper surface in the element region, the gate trenches penetrating the main region and reaching the element drift region. The element region may further include a plurality of p-type field relief regions located below the gate trenches and a plurality of n-type current path regions located between the field relief regions. The element drift region may be located below the field relief regions and the current path regions. The position of each guard ring in the thickness direction of the semiconductor substrate may overlap with the position of each field relief region in the thickness direction.

According to such a configuration, the field relief regions restrict a high electric field from being applied to the gate trenches.

In an embodiment of the semiconductor device disclosed herein, at least one of the plurality of current path regions may be a high concentration current path region having an n-type impurity concentration higher than that of the element drift region.

According to such a configuration, the electrical resistance of the high concentration current path, which is part of the current path, can be reduced.

In an embodiment of the semiconductor device disclosed herein, the outer peripheral region may further have an n-type upper region disposed above the plurality of guard rings and the plurality of spacing regions. The upper region may have an n-type impurity concentration lower than that of the high concentration spacing region.

In an embodiment of the semiconductor device disclosed herein, a mesa portion may be provided on the upper surface of the semiconductor substrate in the outer peripheral region, so that the upper surface of the semiconductor substrate in the outer peripheral region may be located lower than the upper surface of the semiconductor substrate in the element region. The plurality of guard rings may be arranged in an area that includes the bottom of the mesa portion.

As described above, the upper region may be provided above the guard rings, or the mesa portion may be provided above the guard rings. Both configurations can achieve a high breakdown voltage in the outer peripheral region.

In an embodiment of the semiconductor device disclosed herein, the plurality of spacing regions may include a first spacing region and a second spacing region located on an outer periphery of the first spacing region. The second spacing region may be the high concentration spacing region. The first spacing region may have an n-type impurity concentration lower than the n-type impurity concentration of the high concentration spacing region.

A higher electric field is likely to be generated in an inner peripheral region than in the outer peripheral region. According to the configuration described above, the first spacing region (i.e., the region with the lower n-type impurity concentration) is provided on the inner peripheral side in the outer peripheral region, thereby suppressing the generation of the high electric field. The second spacing region (i.e., the high concentration spacing region) is provided on the outer peripheral side in the outer peripheral region, so that a high voltage can be maintained on both sides of the second spacing region. Thus, according to such a configuration, the first spacing region can suppress the high electric field on the inner peripheral side, and the breakdown voltage can be ensured by the second spacing region. Hence, the width of the outer peripheral region can be reduced.

In an embodiment of the semiconductor device disclosed herein, the widths of the guard rings may be reduced toward the outer peripheral side.

According to such a configuration, the generation of high electric field can be suppressed by the wider guard ring on the inner peripheral side in the outer peripheral region.

In an embodiment of a method for manufacturing the semiconductor device, n-type impurities may be ion-implanted simultaneously into the high concentration spacing region and the high concentration current path region.

According to such a configuration, it is possible to produce the semiconductor device efficiently.

An embodiment and various modifications of the present disclosure will be described hereinafter with reference to the drawings.

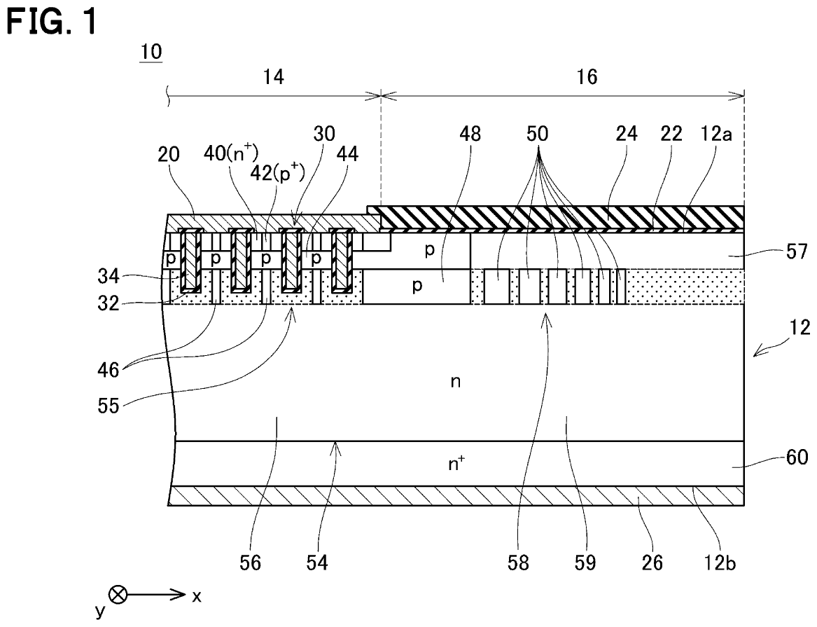

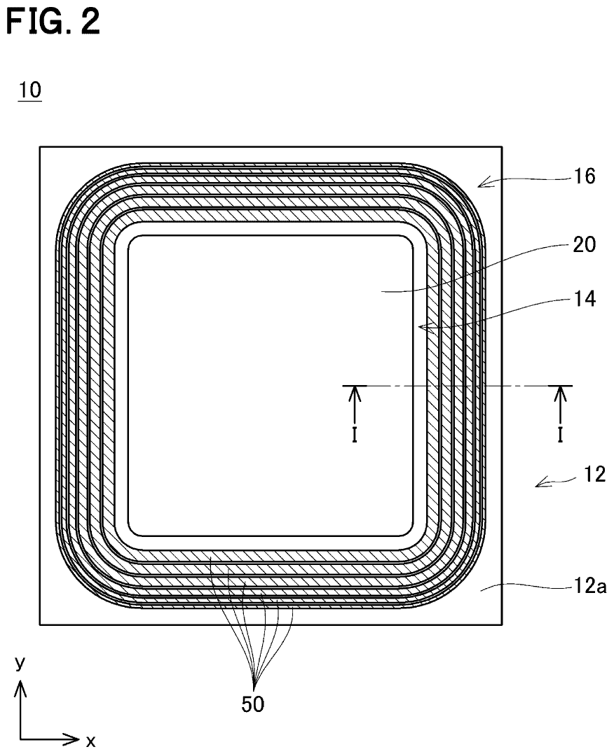

As shown in FIGS. 1 and 2, a semiconductor device 10 of the embodiment includes a semiconductor substrate 12. The semiconductor substrate 12 is made of silicon carbide (SiC). Alternatively, the semiconductor substrate 12 may be made of another semiconductor material, such as silicon (Si) or gallium nitride (GaN). The semiconductor device 10 includes an upper electrode 20 disposed on an upper surface 12a of the semiconductor substrate 12. The upper electrode 20 is in contact with a central portion of the upper surface 12a of the semiconductor substrate 12. Inside the semiconductor substrate 12, a metal oxide semiconductor field effect transistor (MOSFET) is provided in a range covered by the upper electrode 20. Hereafter, the range of the semiconductor substrate 12 covered by the upper electrode 20 is referred to as an element region 14. A region of the semiconductor substrate 12 surrounding the element region 14, that is, a region between the element region 14 and an outer peripheral end surface of the semiconductor substrate 12 is referred to as an outer peripheral region 16. The upper surface 12a of the semiconductor substrate 12 in the outer peripheral region 16 is covered by an interlayer insulating film 22. In the embodiment, the interlayer insulating film 22 is a silicon oxide film. An upper surface of the interlayer insulating film 22 is covered by a protective insulating film 24. In the embodiment, the protective insulating film 24 is a polyimide film. The semiconductor device 10 includes a lower electrode 26 disposed on a lower surface 12b of the semiconductor substrate 12. The lower electrode 26 is in contact with the lower surface 12b of the semiconductor substrate 12 in a range extending over the element region 14 and the outer peripheral region 16.

In the following description, a direction perpendicular to a thickness direction of the semiconductor substrate 12 is referred to as an x direction, and a direction perpendicular to both the thickness direction and the x direction of the semiconductor substrate 12 is referred to as a y direction.

A plurality of gate trenches 30 are provided in the upper surface 12a of the semiconductor substrate 12 in the element region 14. Each of the gate trenches 30 extends linearly in the y direction at the upper surface 12a. The gate trenches 30 are spaced apart from each other in the x direction. A gate insulating film 32 and a gate electrode 34 are disposed in each of the gate trenches 30. The gate insulating film 32 covers the inner surface of the gate trench 30. The gate electrode 34 is insulated from the semiconductor substrate 12 by the gate insulating film 32. An upper surface of the gate electrode 34 is covered with the interlayer insulating film 22. The gate electrode 34 is insulated from the upper electrode 20 by the interlayer insulating film 22.

Inside the semiconductor substrate 12, a plurality of source regions 40, a plurality of contact regions 42, a body region 44, a plurality of field relief regions 46, a deep region 48, and a plurality of guard rings 50 are provided.

The source regions 40 are n-type regions. The source regions 40 are located in the element region 14. Each of the source regions 40 is in contact with the gate insulating film 32 at an upper end portion of a side surface of the corresponding gate trench 30. Each of the source regions 40 is in ohmic contact with the upper electrode 20.

The contact regions 42 are p-type regions. The contact regions 42 are located in the element region 14. Each of the contact regions 42 is in ohmic contact with the upper electrode 20 at a position next to the source region 40.

The body region 44 is a p-type region having a p-type impurity concentration lower than that of the contact region 42. The body region 44 is in contact with the source regions 40 and the contact regions 42 on the lower side of the source regions 40 and the contact regions 42. The body region 44 is in contact with the gate insulating films 32 at positions below the source regions 40.

The field relief regions 46 are p-type regions. The field relief regions 46 are located in the element region 14. Each of the field relief regions 46 extends downward from the body region 44. Each of the field relief regions 46 extends from the body region 44 to a position lower than the bottom end of the gate trench 30. Each of the field relief regions 46 is located at a position without contacting the gate trench 30. Although not shown in the drawings, each of the field relief regions 46 extends linearly in the y direction, similar to the gate trench 30.

The deep region 48 is a p-type region. The deep region 48 is disposed along a boundary between the element region 14 and the outer peripheral region 16. The deep region 48 extends downward from the body region 44. The deep region 48 extends from the body region 44 to a position lower than the bottom end of the gate trench 30. In other words, the deep region 48 extends from the body region 44 to substantially the same depth as the bottom ends of the field relief regions 46.

The guard rings 50 are p-type regions. The guard rings 50 are located in the outer peripheral region 16. As shown in FIG. 2, when the semiconductor substrate 12 is viewed from above, the guard rings 50 each have a ring shape and are arranged in multiple surrounding the element region 14. As shown in FIG. 1, each of the guard rings 50 is separated from the body region 44 and the deep region 48. A space is provided between adjacent guard rings 50, hence the guard rings 50 are separated from each other. In the thickness direction of the semiconductor substrate 12, the position of each guard ring 50 overlaps with the position of each field relief region 46 and the position of the deep region 48. More specifically, each guard ring 50 is located in substantially the same depth range as each field relief region 46 and the deep region 48. As shown in FIGS. 1 and 2, the guard rings 50 have the widths that reduce toward the outer peripheral side. That is, the widths of the guard rings 50 are smaller as the guard rings 50 are closer to the outer peripheral end surface of the semiconductor substrate 12. In other words, the widths of the guard rings 50 gradually narrow from an inner peripheral side toward the outer peripheral side. Hereinafter, the side adjacent to the outer peripheral end surface of the semiconductor substrate 12 will be referred to as the outer peripheral side, and the side further from the outer peripheral end surface of the semiconductor substrate 12 will be referred to as the inner peripheral side.

An n-type drain region 60 is provided inside the semiconductor substrate 12. The drain region 60 is disposed to extend over the element region 14 and the outer peripheral region 16. The drain region 60 is in ohmic contact with the lower electrode 26 in the range extending over the element region 14 and the outer peripheral region 16.

An n-type region 54 is provided inside the semiconductor substrate 12. The n-type region 54 has an n-type impurity concentration lower than the n-type impurity concentration of the drain region 60 and the n-type impurity concentration of the source regions 40. In the element region 14, the n-type region 54 is located between the drain region 60 and the body region 44. In other words, the n-type region 54 is distributed from the position adjoining the drain region 60 to areas located between the adjacent field relief regions 46. Hereinafter, the portion of the n-type region 54 that is located in the area between the adjacent field relief regions 46 is referred to as a current path region 55. Further, the portion of the n-type region 54 that is located below the field relief regions 46 and the current path regions 55 in the element region 14 is referred to as an element drift region 56. In FIG. 1, a part of the n-type region 54 that has an n-type impurity concentration higher than the n-type impurity concentration of the element drift region 56 is hereinafter referred to as a high concentration n-type region, and is shown by dot hatching. As shown in FIG. 1, each of the current path regions 55 is the high concentration n-type region. In other words, in the present embodiment, all the current path regions 55 are the high concentration n-type regions. Each of the current path regions 55 is in contact with the body region 44 on the bottom side thereof. Each of the current path regions 55 is in contact with the gate insulating film 32 at a position below the body region 44. Each of the current path regions 55 is in contact with a side surface of the corresponding field relief region 46. The element drift region 56 is in contact with each of the respective current path regions 55 and each of the field relief region 46 on the bottom sides thereof.

The n-type region 54 is disposed to extend over the element region 14 and the outer peripheral region 16. In the outer peripheral region 16, the n-type region 54 is distributed from the position adjoining the drain region 60 to the upper surface 12a of the semiconductor substrate 12. The n-type region 54 is distributed in spaces between the adjacent guard rings 50 to separate the guard rings 50 from each other. Also, the n-type region 54 separates the guard rings 50 from the deep region 48 and the body region 44. Hereinafter, the portions of the n-type region 54 that are located between the adjacent guard rings 50 in the outer peripheral region 16 are referred to as spacing regions 58. Further, the portion of the n-type region 54 that is located above the guard rings 50 and the spacing regions 58 in the outer peripheral region 16 is referred to as an upper region 57. Moreover, the portion of the n-type region 54 that is located below the guard rings 50 and the spacing regions 58 in the outer peripheral region 16 is referred to as an outer drift region 59. Each of the spacing regions 58 is the high concentration n-type region. In other words, in the present embodiment, all the spacing regions 58 are the high concentration n-type regions. The upper region 57 and the outer drift region 59 have substantially the same n-type impurity concentration as the element drift region 56. The upper region 57 is in contact with each of the guard rings 50 and each of the spacing regions 58 on the upper sides thereof. The outer drift region 59 is in contact with each of the guard rings 50 and each the spacing regions 58 on the lower sides thereof. The outer drift region 59 and the element drift region 56 are continuous with each other in a lateral direction.

Next, an operation of the semiconductor device 10 will be described. When the semiconductor device 10 is used, the lower electrode 26 is applied with a potential higher than that of the upper electrode 20. When the gate electrode 34 is applied with a potential equal to or higher than a gate threshold, a channel is formed in the body region 44 at a location adjacent to the gate insulating film 32. Thus, electrons flow from the source region 40 to the drain region 60 through the channel, the current path region 55 and the element drift region 56. That is, the MOSFET is turned on. Since the current path region 55 has the high n-type impurity concentration, the electrical resistance of the current path region 55 is low. Thus, the electrons can pass through the current path region 55 with low loss. For this reason, the on-resistance of the MOSFET is low.

When the potential of the gate electrode 34 is reduced to the value below the gate threshold, the channel disappears and the flow of electrons stops. As a result, the MOSFET is turned off. When the MOSFET is turned off, a depletion layer spreads from the body region 44 and the field relief regions 46 to the current path regions 55 and the element drift region 56. The depletion layer spread over the current path regions 55 and the element drift region 56 maintains the voltage applied between the body region 44 and the drain region 60. In addition, since the field relief region 46 is provided, the depletion layer easily spread around the bottom end of the gate trench 30. As such, the application of a high electric field to the gate insulating film 32 located at the bottom end of the gate trench 30 is restricted.

When the MOSFET is turned off, the depletion layer spreads from the body region 44 and the deep region 48 to the n-type region 54 in the outer peripheral region 16, that is, to the upper region 57, the spacing regions 58, and the outer drift region 59. The potential of each guard ring 50 is floating. The depletion layer extending from the body region 44 and the deep region 48 extends toward the outer peripheral side in the n-type region 54 via the multiple guard rings 50. The multiple guard rings 50 promote the spreading of the depletion layer toward the outer peripheral side. The depletion layer spread over the n-type region 54 in the outer peripheral region 16 maintains the voltage applied between the body region 44 and the outer peripheral end surface of the semiconductor substrate 12.

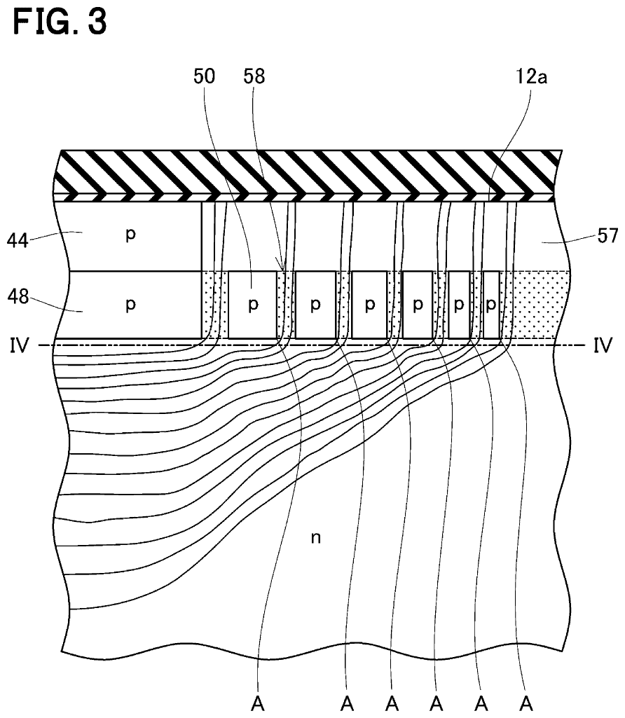

FIG. 3 shows the distribution of equipotential lines in the outer peripheral region 16, when the MOSFET is in an off state. As shown in FIG. 3, the equipotential lines extend laterally in an area below the deep region 48. The equipotential lines bend upward at the lower ends of the spacing regions 58, enter the spacing regions 58, and extend to the upper surface 12a. As the equipotential lines enter each spacing region 58, the electric fields of the guard rings 50 are higher as the guard rings 50 are closer to the inner peripheral side, and are lower as the guard rings 50 are closer to the outer peripheral side. In other words, the electric fields of the guard rings 50 reduce as the guard rings 50 are further from the deep region 48. In the present embodiment, the n-type impurity concentration of each of the spacing regions 58 is higher than the n-type impurity concentration of the element drift region 56. Therefore, the high electric field is more likely to occur in each of the spacing regions 58, and thus more equipotential lines are likely to enter each of the spacing regions 58. As such, a potential difference can easily occur between the adjacent guard rings 50. For this reason, the potential difference that can be held between the guard rings 50 is large, and the potential difference that can be held in the outer peripheral region 16 is large. Therefore, even if the outer peripheral region 16 is narrow, the outer peripheral region 16 can realize the high breakdown voltage. As described above, by increasing the n-type impurity concentration of the spacing regions 58 to be higher than the n-type impurity concentration of the element drift region 56, the breakdown voltage performance of the outer peripheral region 16 can be improved and the width of the outer peripheral region 16 can be reduced.

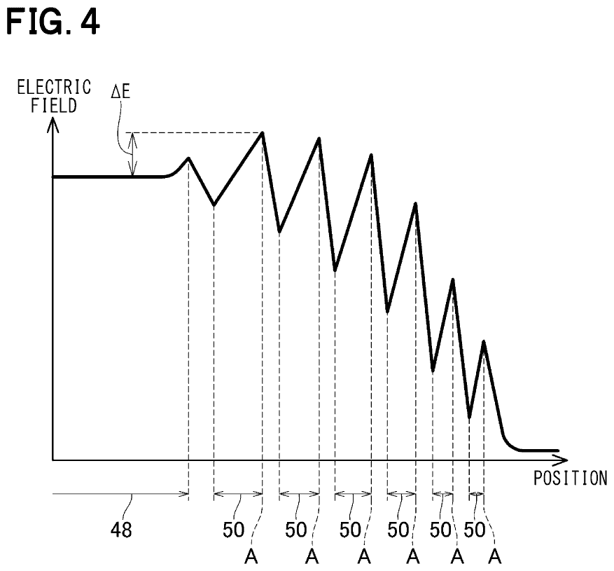

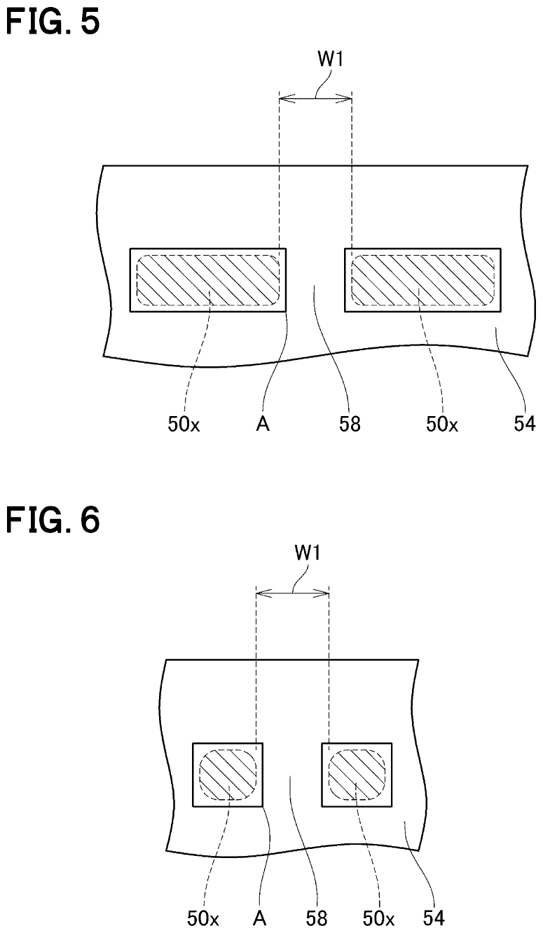

FIG. 4 shows the electric field distribution in the outer drift region 59 at the position taken along a line IV-IV in FIG. 3, that is, at the position below the guard rings 50. In FIG. 4, the horizontal axis represents the positions of the respective guard rings 50 located above the line IV-IV. As described above, the electric fields of the guard rings 50 are higher as the guard rings 50 are closer to the inner peripheral side, and are lower as the guard rings 50 are closer to the outer peripheral side. Thus, as shown in FIG. 4, in the outer drift region 59 located below the guard rings 50, the electric field becomes smaller from the inner peripheral side toward the outer peripheral side. In addition, the electric field is concentrated at the position where the equipotential line bends. Therefore, the electric field has a peak locally in the vicinity of an edge A on the outer peripheral side of the lower surface of each guard ring 50. The value of each peak lowers from the inner peripheral side toward the outer peripheral side. As described above, a high electric field is likely to occur in the vicinity of the edge A of the guard ring 50 on the inner peripheral side. The electric fields generated in the vicinity of the edges A of the guard rings 50 on the inner peripheral side are higher than the electric field generated below the deep region 48. In this regard, in the semiconductor device of the present embodiment, since the widths of the guard rings 50 are larger as the guard rings 50 are closer to the inner peripheral side, the high electric fields in the vicinity of the guard rings 50 on the inner peripheral side are suppressed. The suppression of the high electric fields in the vicinity of the guard rings 50 on the inner peripheral side will be described below with reference to FIGS. 5 and 6.

FIG. 5 shows the case where the width of the guard ring 50 is large, and FIG. 6 shows the case where the width of the guard ring 50 is small. In FIGS. 5 and 6, a shaded region 50x represents a non-depletion region that remains in the guard ring 50 when the MOSFET is in the off state. In other words, in FIGS. 5 and 6, the guard ring 50 and the n-type region 54 are depleted outside of the region 50x. As shown in FIG. 5, in the case where the width of the guard ring 50 is large, since the volume of the guard ring 50 is large, the width of the depletion layer extending from the pn junction into the guard ring 50 is small. Therefore, between the adjacent guard rings 50, the space W1 between the non-depletion regions 50x is narrow. On the other hand, as shown in FIG. 6, in the case where the width of the guard ring 50 is small, since the volume of the guard ring 50 is small, the width of the depletion layer extending from the pn junction into the guard ring 50 is large. Therefore, between the adjacent guard rings 50, the space W1 between the non-depletion regions 50x is large. In the case where the space W1 is small as shown in FIG. 5, it is more difficult for equipotential lines to enter the spacing region 58 than in the case where the space W1 is large as shown in FIG. 6. Therefore, in the case where the space W1 is small as shown in FIG. 5, the electric field generated in the vicinity of the edge A is smaller than that in the case where the space W1 is large as shown in FIG. 6. When the widths of the guard rings 50 are larger on the inner peripheral side, as shown in FIG. 3, the high electric field concentration near the edges A of the guard rings 50 on the inner peripheral side is suppressed. As a result, as shown in FIG. 4, the difference ΔE between the peak value of the electric field in the vicinity of the edge A of the guard ring 50 on the inner peripheral side and the electric field below the deep region 48 can be reduced. In addition, the electric field concentration is likely to occur in the vicinity of the edge A of the guard ring 50 on the outer peripheral side. However, as shown in FIG. 4, even if the electric field concentration occurs in the guard ring 50 on the outer peripheral side, the electric field is not so high and no problem occurs. Since the widths of the guard rings 50 on the outer peripheral side are reduced, the width of the outer peripheral region 16 can be reduced. According to the configuration described above, the overall width of the outer peripheral region 16 can be reduced while suppressing the generation of high electric fields by the guard rings 50 on the inner peripheral side.

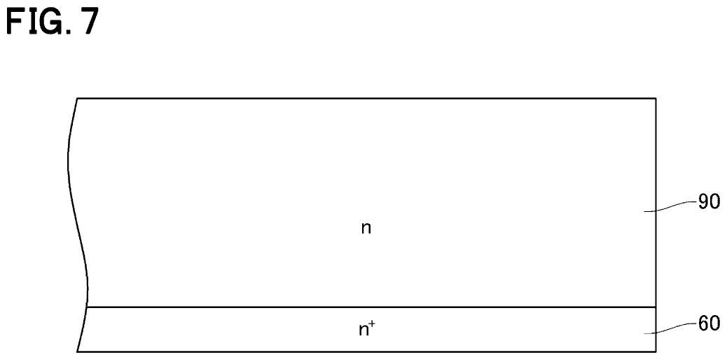

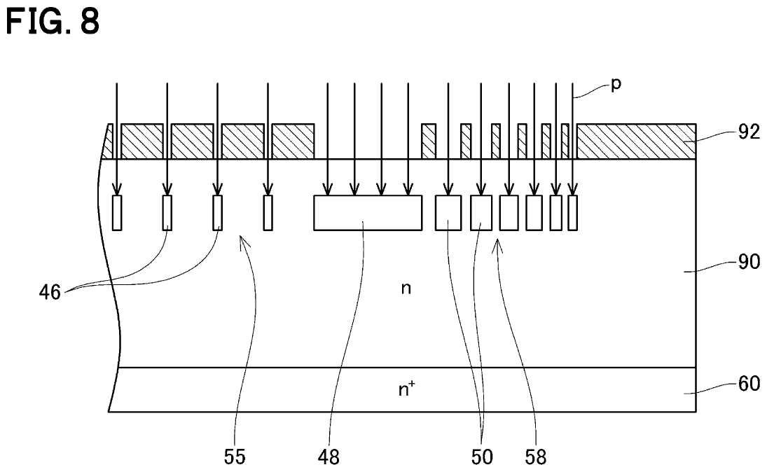

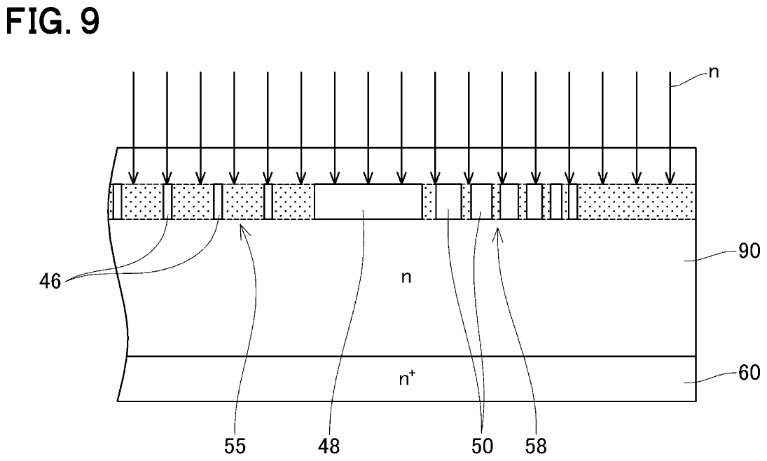

Next, a manufacturing method of the semiconductor device 10 will be described. The semiconductor device 10 is produced using a semiconductor substrate composed of the drain region 60. First, as shown in FIG. 7, an n-type layer 90 is epitaxially grown on the drain region 60. The n-type layer 90 has the same n-type impurity concentration as the element drift region 56. Next, as shown in FIG. 8, the p-type impurity is ion-implanted into the n-type layer 90 selectively through a mask 92 to form the field relief region 46, the deep region 48, and the guard rings 50. Next, as shown in FIG. 9, the n-type impurity is ion-implanted to the entire semiconductor substrate to the same depth as the field relief region 46, the deep region 48, and the guard rings 50. In this case, the n-type impurity is implanted at a lower concentration than in the field relief region 46, the deep region 48, and the guard rings 50. As a result, the high concentration n-type regions with the higher n-type impurity concentration than the element drift region 56 is formed in the current path regions 55 and the spacing regions 58. Next, the source region 40, the contact region 42, and the body region 44 are formed by ion implantation. Thereafter, necessary components such as electrodes and insulating films are formed to complete the semiconductor device 10.

According to the manufacturing method described above, the ion implantations of the p-type impurities into the field relief regions 46 and the guard rings 50 can be performed simultaneously, and the ion implantations of the n-type impurities into the current path regions 55 and the spacing regions 58 can be performed simultaneously. In the manufacturing method described above, it is not necessary to form a mask in the ion implantations for the current path regions 55 and the spacing regions 58. According to this manufacturing method, it is possible to produce the semiconductor devices 10 efficiently.

In the embodiment described above, the spacing regions 58 formed with the high concentration n-type regions correspond to an example of a high concentration spacing region. In the embodiment described above, the current path regions 55 formed with the high concentration n-type regions correspond to an example of a high concentration current path region. In the embodiment described above, the contact regions 42 and the body region 44 correspond to an example of a main region.

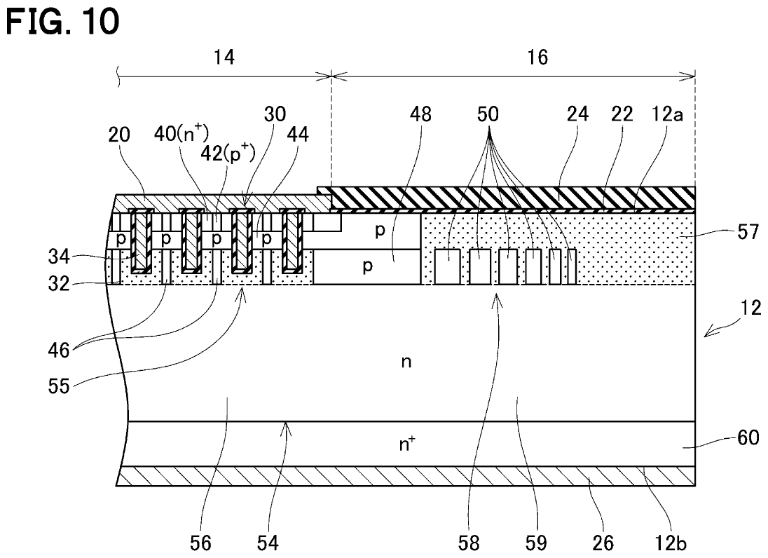

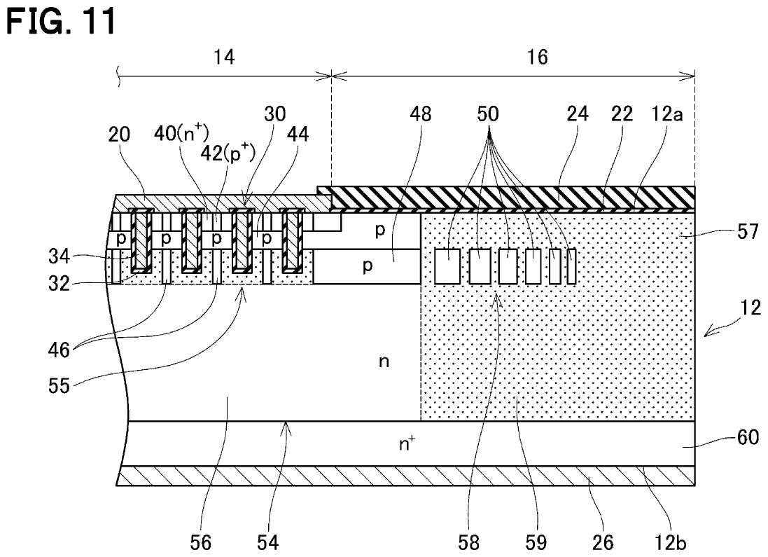

In the embodiment described above, in the outer peripheral region 16, the high concentration n-type regions having the higher n-type impurity concentration than the element drift region 56 (i.e., the dot-hatched regions in FIG. 1) are formed in the spacing regions 58. However, the high concentration n-type region may be formed in a region outside of the spacing regions 58, in addition to the spacing regions 58. For example, as shown in FIG. 10, the high concentration n-type region may be formed across the spacing regions 58 and the upper region 57. As another example, as shown in FIG. 11, the high concentration n-type region may be formed across the spacing regions 58, the upper region 57, and the outer drift region 59.

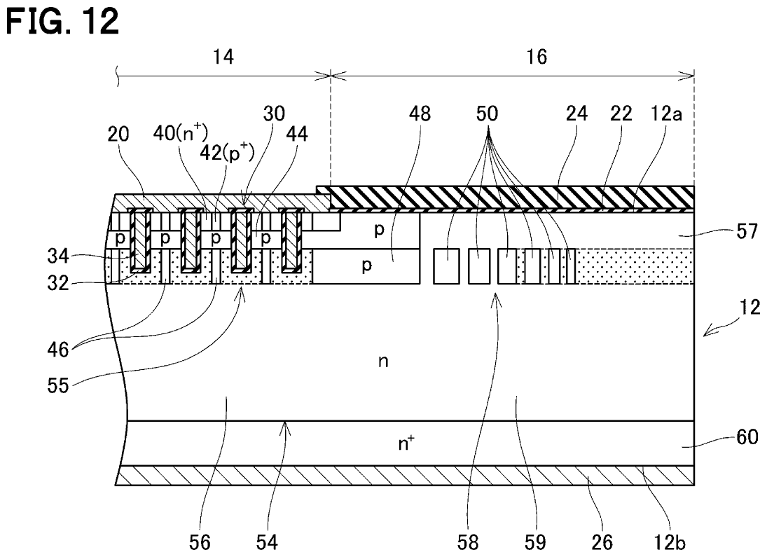

In the embodiment described above, the high concentration n-type region is formed in all of the spacing regions 58. Alternatively, the high concentration n-type region may be formed only in some of the spacing regions 58. For example, as shown in FIG. 12, the high concentration n-type region may be formed in the spacing regions 58 on the outer peripheral side (i.e., in the spacing regions 58 closer to the outer peripheral end surface of semiconductor substrate 12), but may not be formed in the spacing regions 58 on the inner peripheral side (i.e., in the spacing regions 58 closer to the element region 14). That is, the spacing regions 58 on the outer peripheral side can be the high concentration spacing regions and the spacing regions 58 on the inner peripheral side can have the n-type impurity concentration lower than that of the high concentration spacing regions. As described above, in the case where the high concentration n-type region is formed in the spacing regions 58, a high potential difference can be maintained by the spacing regions 58. On the other hand, a high electric field is easily generated in the spacing regions 58. The electric field can be relieved by lowering the n-type impurity concentration of the spacing regions 58 on the inner peripheral side, where the high electric fields are easily generated, as shown in FIG. 12. It is also possible to narrow the line width of the spacing regions 58 on the outer peripheral side by increasing the n-type impurity of the spacing regions 58 on the outer peripheral side, where the high electric fields are less likely to occur. In this case, it is possible to reduce the width of the outer peripheral region 16.

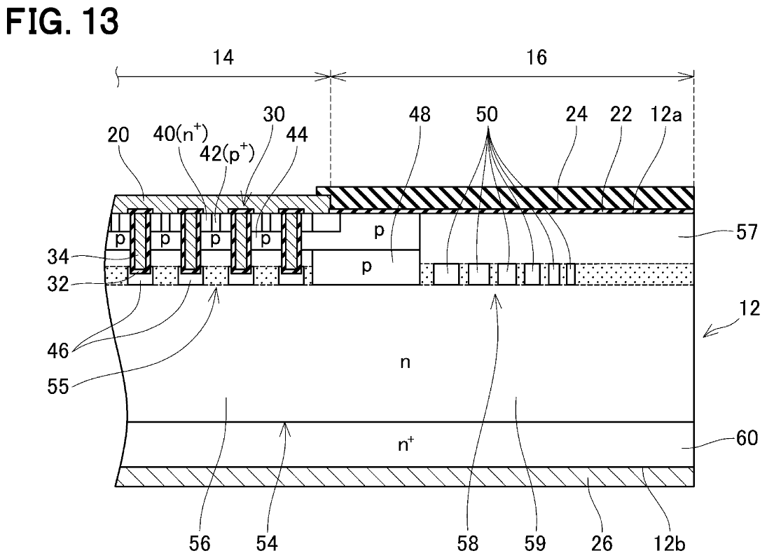

In the embodiment described above, the field relief region 46 is connected to the body region 44. Alternatively, the field relief region 46 may be separated from the body region 44 and the potential of the field relief region 46 may be floating. In the embodiment described above, the field relief region 46 is formed at an intermediate position between the adjacent gate trenches 30. Alternatively, as shown in FIG. 13, the field relief region 46 may be located below the gate trench 30. As shown in FIG. 13, the field relief region 46 may be in contact with the bottom end of the gate trench 30. As another example, the field relief region 46 may be separated from the bottom end of the gate trench 30. Even when the field relief region 46 is located below the gate trench 30, the field relief region 46 may be connected to the body region 44 or the field relief region 46 may be separated from the body region 44.

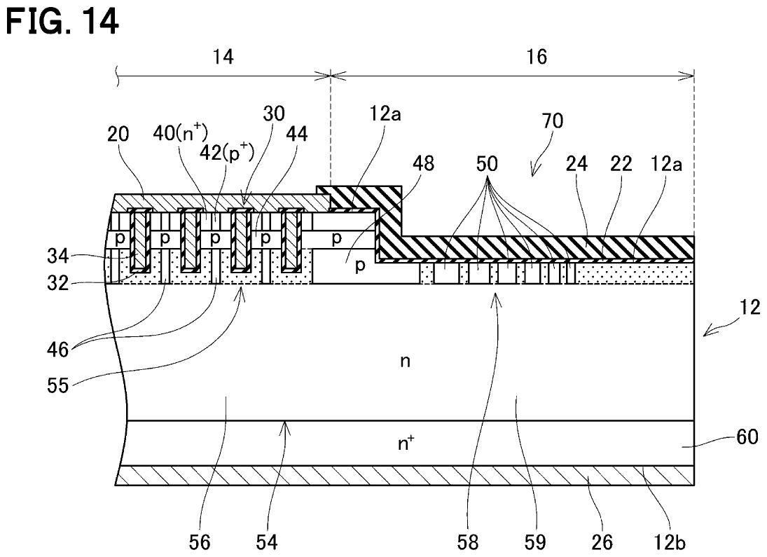

In the embodiment described above, the upper surface 12a of the semiconductor substrate 12 is positioned at the same height in the element region 14 and the outer peripheral region 16. Alternatively, as shown in FIG. 14, the upper surface 12a may be formed with a mesa portion 70 in the outer peripheral region 16, so that the upper surface 12a in the outer peripheral region 16 is located lower than the upper surface 12a in the element region 14. In this case, the guard rings 50 may be disposed in an area including the bottom surface of the mesa portion 70, that is, in an area including the upper surface 12a in the outer peripheral region 16. In other words, the n-type upper region 57 may not be present above the guard rings 50. Also in this configuration, the breakdown voltage in the outer peripheral region 16 can be improved by the guard rings 50.

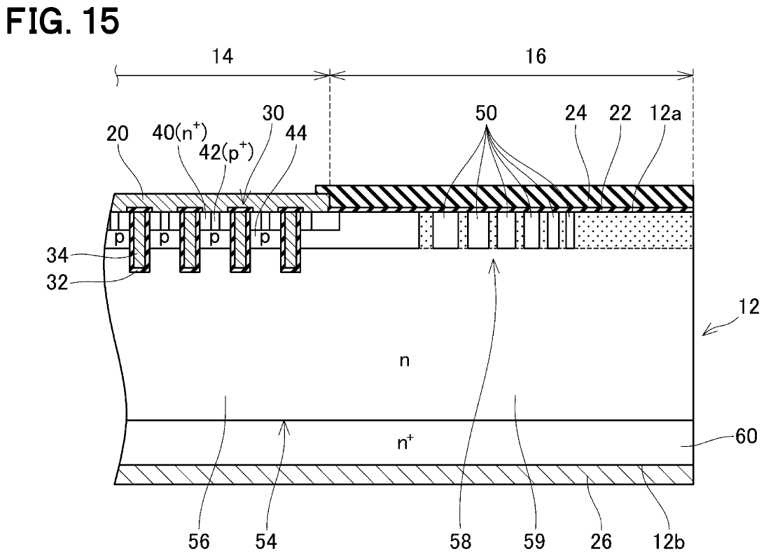

In the embodiment described above, the field relief regions 46 are provided in the element region 14. Alternatively, the field relief region 46 may not be provided in the element region 14. In this case, as shown in FIG. 15, the guard rings 50 may be formed at the depth that overlaps with the body region 44.

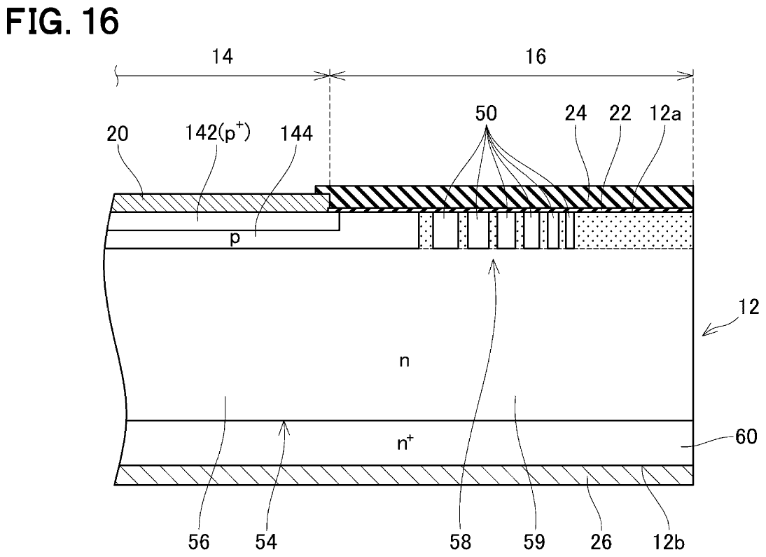

In the embodiment described above, the MOSFET is formed in the element region 14. Alternatively, another switching element such as insulated gate bipolar transistor (IGBT) may be formed in the element region 14. For example, as shown in FIG. 16, a diode may be formed in the element region 14. In the example of FIG. 16, a p-type contact region 142 and a p-type anode region 144 are formed in the element region 14. The anode region 144 has a p-type impurity concentration lower than that of the contact region 142. The contact region 142 is in ohmic contact with the upper electrode 20, and the anode region 144 is in contact with the contact region 142 on the lower side thereof. The element drift region 56 is in contact with the anode region 144 on the lower side thereof. The guard rings 50 are formed at a depth that overlaps with the anode region 144.

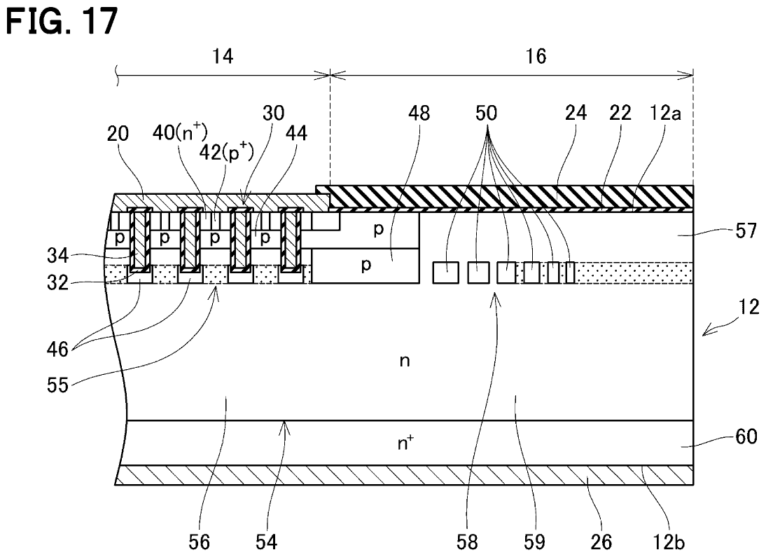

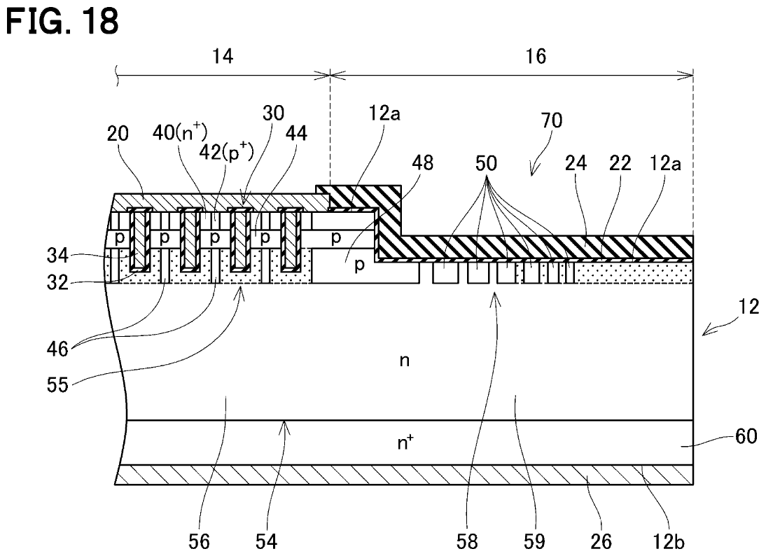

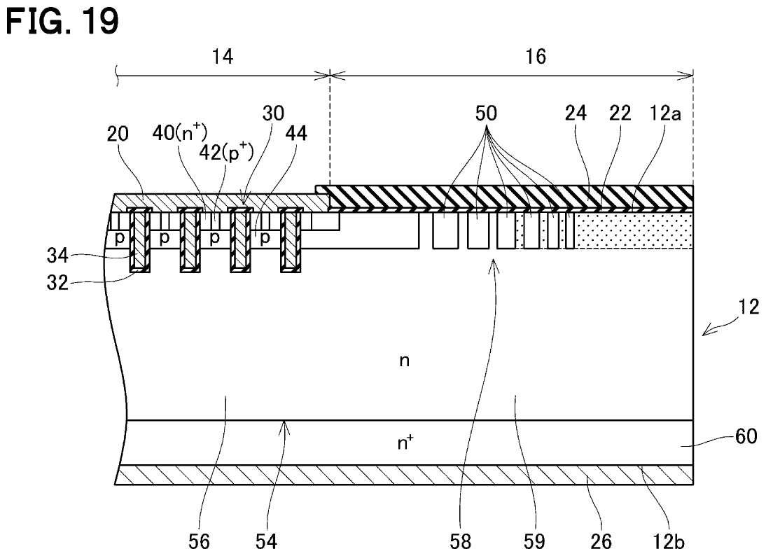

In the configurations shown in FIGS. 13, 14 and 15, the high concentration n-type region may not be formed in the spacing regions 58 on the inner peripheral side, as in the configuration shown in FIG. 12. For example, as shown in FIGS. 17, 18, and 19, the high concentration n-type region may be formed in the spacing regions 58 on the outer peripheral side, but the high concentration n-type region may not be formed in the spacing regions 58 on the inner peripheral side.

While the present disclosure has been described with reference to the embodiment and modifications thereof, it is to be understood that the disclosure is not limited to the embodiment and modifications and constructions thereof. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A semiconductor device comprising:
a semiconductor substrate having an element region and an outer peripheral region disposed on a periphery of the element region; and
an upper electrode disposed in contact with an upper surface of the semiconductor substrate in the element region, wherein
the element region includes:
a p-type main region being in contact with the upper electrode; and
an n-type element drift region located below the main region, the outer peripheral region includes:
a plurality of p-type guard rings disposed in multiple ring shapes surrounding the element region when viewed in a thickness direction of the semiconductor substrate;
a plurality of n-type spacing regions disposed between the plurality of p-type guard rings;
an n-type outer drift region continuous with the n-type element drift region and located below the plurality of p-type guard rings and the plurality of n-type spacing regions; and
an n-type upper region disposed above the plurality of p-type guard rings and the plurality of n-type spacing regions,
at least one of the plurality of n-type spacing regions is a high concentration spacing region having an n-type impurity concentration higher than that of the n-type element drift region, and
the upper region has an n-type impurity concentration lower than that of the high concentration spacing region.

2. The semiconductor device according to claim 1, wherein
the semiconductor substrate is formed with a plurality of gate trenches in the upper surface in the element region, each of the gate trenches penetrating the p-type main region and reaching the n-type element drift region,
the element region further includes:
a plurality of p-type field relief regions located at positions lower than the plurality of gate trenches; and
a plurality of n-type current path regions located between the plurality of p-type field relief regions,
the n-type element drift region is disposed below the plurality of p-type field relief regions and the plurality of n-type current path regions, and
the plurality of p-type guard rings are located at a position overlapping with a position of the plurality of p-type field relief regions in the thickness direction of the semiconductor substrate.

3. The semiconductor device according to claim 2, wherein
at least one of the plurality of n-type current path regions is a high concentration current path region having an n-type impurity concentration higher than that of the n-type element drift region.

4. The semiconductor device according to claim 1, wherein
the plurality of n-type spacing regions include a first spacing region and a second spacing region that is located on an outer peripheral side of the first spacing region,
the second spacing region is the high concentration spacing region, and
the first spacing region has an n-type impurity concentration lower than that of the high concentration spacing region.

5. The semiconductor device according to claim 4, wherein
the plurality of p-type guard rings have widths that reduce as a function of distance from the element region.

6. A method for manufacturing the semiconductor device according to claim 3, comprising:
performing ion-implantation of n-type impurities simultaneously to the high concentration spacing region and the high concentration current path region.
